(19) United States
(12) Patent Application Publication
(10) Pub. No.: US 2001/0042919 A1
(43) Pub. Date: Nov. 22, 2001

(54) SEMICONDUCTOR DEVICE AND MANUFACTURING METHOD THEREOF

(76) Inventors: Manabu Tomita, Ibaraki (JP); Takashi Hayakawa, Akishima-shi (JP); Masayuki Yasuda, Yokohama-shi (JP); Michio Nishimura, Yamanashi (JP); Minoru Ohtsuka, Ibaraki (JP); Masayuki Kojima, Tokyo (JP); Kazuo Yamazaki, Tokyo (JP)

Correspondence Address: TEXAS INSTRUMENTS INCORPORATED, P O BOX 655474, M/S 3999, DALLAS, TX, 75265

(21) Appl. No.: 09/387,477

(22) Filed: Sep. 1, 1999

(30) Foreign Application Priority Data
Sep. 1, 1998 (JP) 10(1998)-262,461

(51) Int. Cl. H01L 23/48; H01L 21/302

(52) U.S. Cl. 257/758; 438/723

(57) ABSTRACT

The invention relates to a method for forming connection holes reliably by making contact resistance low and uniform in semiconductor devices. Insulating layer 3, that includes SOG layer 7, is plasma etched using an etching gas with a small quantity of a gas with a low C/F ratio, such as CHF₃, mixed with a gas with a high C/F ratio, such as C₄F₈/Ar/O₂ at a ratio of 1:3.

### FIELD OF THE INVENTION

This invention pertains to a semiconductor device that has an insulating layer on a semiconductor substrate, and in particular to a semiconductor device with a multilayer wiring structure where a lower conducting layer is formed on a semiconductor substrate as an electrode or wiring, a connection hole is formed in an insulating layer that covers this lower conducting layer, and an upper conducting layer that is connected to the aforementioned lower conducting layer is formed in the aforementioned connection hole as an electrode or wiring, and to a manufacturing method thereof.

### BACKGROUND OF THE INVENTION

In semiconductor integrated circuit devices, a multilayer wiring structure is indispensable for connecting upper and lower electrodes or wiring and is formed with the following method.

As shown in FIG. 1a, before the connection hole (via hole) is formed, lower wiring 2 is formed on SiO₂ layer 1 provided on a silicon semiconductor substrate, and this is covered with insulating layer 3. Lower wiring 2 is made of a stacked structure where 0.1 μm thick titanium nitride (hereafter TiN) layer 4, 0.4 μm thick aluminum alloy (for example Al—Si—Cu or Al—Cu) layer 5, 0.01 μm thick titanium (hereafter Ti) layer 6, and 0.075 μm TiN layer 7 are stacked in that order by sputtering or the like. Then, insulating layer 3 is made of a stacked structure where a 0.3 μm thick SiO₂ layer (hereafter PTEOS layer) formed from tetraethyl orthsilicate with plasma generated using an oxidant, e.g., O₃, as the liquid source, a 0.4 μm silicon-on-glass layer (hereafter SOG layer) 9 formed by coating with and baking a chemical solution where SiOx is dissolved in alcohol, and a 0.3 μm PTEOS layer 10, the top layer, are stacked in that order. Note that FIG. 1a is a case where the thickness of SOG layer 8 on lower wiring 2 is small, and it is the same even in cases where its thickness is large, as in FIG. 2a.

Next, as shown in FIG. 1b and FIG. 2b, using a photoresist with a prescribed pattern (not shown) as the mask, plasma etching is performed using a fluorocarbon etching gas, and connection hole (via hole) 11 that connects with lower wiring 3 is formed through insulating layer 3. Additionally, as indicated by the imaginary line, upper wiring 12, of aluminum or the like, is formed by sputtering or lithography technology, and connects with lower wiring (2) through connection hole 11.

In this dry etching, the parallel flat RIE type device shown in FIG. 6 is generally used. This uses a device [UNITY IEM (ion energy modulation)] that has high-frequency power sources 15 and 16 for the two upper and lower electrodes 13 and 14, respectively. This device is generally termed a medium-density plasma etching device.

For this plasma etching, the following two types of gases are primarily used as etching gases under the conditions below.

(1) Mixed gas of CHF₃/Ar/O₂ (selection ratio for Si₃N₄ and TiN is low.)

CHF₃/Ar/O₂=50/500/9 sccm, pressure=50 mT.

RF (upper electrode/lower electrode)=2200/1000 W,

back pressure (center section/edge section)=10/35 T,

temperature (lower electrode/upper electrode/titanium bar side wall)=−20/30/40° C.

(2) Mixed gas of C₄F₈/Ar/O₂ (selection ratio for Si₃N₄ and TiN is high.)

C₄F₈/Ar/O₂=18/420/11 sccm, pressure=30 mT

RF (upper electrode/lower electrode)=2200/1400 W,

back pressure (center section/edge section)=10/35 T,

temperature (lower electrode/upper electrode/titanium bar side wall)=−20/30/40° C.

However, dry etching using the aforementioned etching gases has problems such as the following in either case.

(1) when CHF₃/Ar/O₂ mixed gas is used for via hole dry etching, TiN layer 7 (and additionally TiN layer 6) on Al alloy layer 5 is etched off. In this case, the problem is that when Al alloy layer 5 below TiN layer 7 is exposed, a fluorinated layer (AlFx layer) remains on the surface of the aluminum after etching. Higher contact resistance and increased variation are produced by this AlFx layer, and it is generally known that this adversely affects device performance. Here, in via holes that currently are of a size of around 0.3-0.4 μm, this AlFx layer is removed by sputter etching when metal (for the upper wiring) is deposited in the next process, so it is not a problem at the present time. However, as the size of via holes becomes smaller in future, sputter etching will be insufficient, and it is expected that the fluorinated layer will not be removed.

(2) And in cases where a C₄F₈/Ar/O₂ mixed gas with a high selection ratio for TiN on Al alloy 5 is used, etching on TiN layer 7 will be stopped, so the following problems are produced.

(a) SOG layer 9, where SiN bonds are present in the film, is used as an insulating layer, so with this gas system that has a high selection ratio for Si₃N₄, the selectivity is also high for SOG, and etching is stopped by SOG layer 9. This is more noticeable the smaller the diameter of the via hole (refer to FIG. 3a).

(b) In addition, to even out with SOG layer 9, the thickness of the interlayer film (insulating layer 3) on lower wiring 2 varies according to location, so when a via hole is formed in this type of location, there is the possibility that a hole will not be formed in thick portions of the interlayer film (that is, in the prescribed etching time, etching will not reach the lower section).

The purpose of this invention is to provide a method by which contact resistance can be made lower and uniform connection holes can reliably be formed, and a semiconductor device produced by this.

### SUMMARY OF THE INVENTION

The present inventors performed intensive research concerning the aforementioned problems with the prior art and as a first result considered the situation discussed below.

In the case of gas with a low ratio of carbon atoms to fluorine atoms (that is, C/F ratio), such as the aforementioned CHF₃ (or CF₄), it is generally known that the quantity of F radicals in the plasma is large and that Si, Si₃N₄ or a resist will be easily etched. In contrast with this, in the case of gas with a high C/F ratio, such as the aforementioned C₄F₈, the quantity of CFx radicals in the plasma is large; these CFx radials are deposited on a film and function to prevent Si or Si₃N₄ from reacting with the F radicals. It is also generally known that the result is that these films are difficult to etch.

In short,

(1) in the case of CF₄ gas (low C/F ratio), the quantity of F radicals in the plasma is large and Si, Si₃N₄ or resists are easily etched.

(2) In the case of CHF₃ gas (slightly lower C/F ratio), there are fewer F radicals than with CF₄ gas. This is due to the fact that H bonds with F and HF is produced. Thus, it will be difficult for Si or resists to be etched. However, in the case of devices that generate high-density plasma that have been used recently, the F radicals increase due to reseparation of the CFx radicals, so it will be easier to remove Si, Si₃N₄ or resists than with conventional low-density plasma.

(3) In the case of C₄F₈ gas (high C/F ratio), the quantity of CFx radicals is greater than in the other gases. Thus, there will be many CFx radicals deposited on the film, so it will be more difficult to remove Si, Si₃N₄ or resists than with other gases.

On the basis of these facts, the present inventors satisfactorily solved the problems of the prior art by adding a small quantity of CHF₃ (low C/F ratio gas) to C₄F₈/Ar/O₂ (high C/F ratio gas) and discovered that the purpose of this invention could be realized, and they arrived at this invention.

In short, this invention is associated with a semiconductor device manufacturing method that includes a process where an insulating layer on a semiconductor substrate is etched (especially plasma etched) using a mixed gas of multiple types of fluorocarbons with different ratios of carbon atoms to fluorine atoms (C/F ratio) (for example, a mixed gas of C₄F₈ and CHF₃).

With the manufacturing method of this invention, by adding a small quantity, for example, in the ratio of 1:3, of a gas with a low C/F ratio, such as CHF₃, to a gas with a high C/F ratio, such as C₄F₈/Ar/O₂, the following remarkable effects can be obtained.

(1) The SOG etching rate can be increased (refer to FIG. 3 and FIG. 4 below). By adding a gas with a low C/F ratio, the F radicals in the plasma are increased, and the SOG etching rate, which includes Si—N bonds, is increased by this.

(2) An extreme increase in the TiN etching rate can be prevented (selection ratio 20 or greater) (refer to FIG. 5 below). A decrease in the selection ratio for TiN due to the increase in F radicals is a concern, but an extreme increase in F radicals is suppressed by the reaction of F radicals caused by H in the CHF₃ gas, for example, and a selection ratio of 20 or greater can be obtained.

Due to such remarkable effects, semiconductor devices produced with the manufacturing method of this invention will have a unique structure and will be superior in terms of lower contact resistance and uniformity thereof.

In short, the semiconductor device based on this invention is characterized by having a lower conducting layer that has a titanium nitride layer on the surface formed on a semiconductor substrate as the electrode or wiring, a connection hole that is formed in an insulating layer that includes a spin-on glass layer to cover this lower conducting layer, and an upper conducting layer connected to the aforementioned lower conducting layer that is formed in the aforementioned connecting hole as electrode or wiring; the aforementioned connection hole is formed to the middle position of the thickness of the aforementioned titanium nitride layer through the aforementioned insulating layer.

### BRIEF DESCRIPTION OF THE DRAWINGS

FIG. 1 is a cross section of major parts showing a comparison of processes when multilayer wiring structures are formed.

FIG. 2 is a cross section of major parts showing a comparison of processes when multilayer wiring structures are formed.

FIG. 3 likewise is a graph showing a comparison of the dependence of the SOG etching rate on the etching gas composition used for forming a multilayer wiring structure.

FIG. 4 likewise is a graph showing the dependence of the SOG etching rate on the etching gas composition used for forming a multilayer wiring structure.

FIG. 5 likewise is a graph showing the dependence of the selection ratio for TiN on the etching gas composition used for forming a multilayer wiring structure.

FIG. 6 likewise is a schematic diagram of a plasma etching device used for dry etching in forming a multilayer wiring structure.

### REFERENCE NUMERALS AND SYMBOLS AS SEEN IN THE DRAWINGS

In the drawings, 1 represents a SiO₂ layer, 2 a lower wiring, 3 an insulating layer (interlayer insulating film), 4, 7 a TiN layer, 5 an Al alloy layer (or Al layer), 6 a Ti layer, 8, 10 a PTEOS layer, 9 a SOG layer, 11, 21 a via hole and 12 an upper wiring.

### DESCRIPTION OF EMBODIMENTS

In the manufacturing method and semiconductor device of this invention, the aforementioned mixed gas in which equal quantities or less (1:1 or less) of a second fluorocarbon gas with a small C/F ratio to a first fluorocarbon gas with large C/F ratio are mixed is used.

C₄F₈ can be used as the aforementioned first fluorocarbon gas, and at least one selected from a group composed of CHF₃, CH₂F₂ and CF₄ can be used as the aforementioned second fluorocarbon gas.

So, a lower conducting layer can be formed on the aforementioned semiconductor substrate as an electrode or wiring, a connection hole can be formed by the aforementioned etching in the aforementioned insulating layer that covers this lower conducting layer, and an upper conducting layer that is connected to the aforementioned lower conducting layer can be formed in the aforementioned connection hole.

In this case, the aforementioned lower conducting layer has a titanium nitride layer on the surface on which the aforementioned connection hole is formed, and the aforementioned insulating layer includes a spin-on glass layer. For example, the aforementioned lower conducting layer is made of a stacked structure where a titanium nitride (TiN) layer, a layer of aluminum or an alloy thereof, a titanium (Ti) layer, and a titanium nitride (TiN) layer are stacked in that order, and the aforementioned insulating layer is made of a stacked structure where a silicon oxide layer formed from tetraethyl orthosilicate (particularly a PTEOS layer), a spin-on glass layer, and a silicon oxide layer formed from tetraethyl orthosilicate (particularly a PTEOS layer) are stacked in that order.

Next, this invention will be explained for a preferred embodiment by referring to the figures.

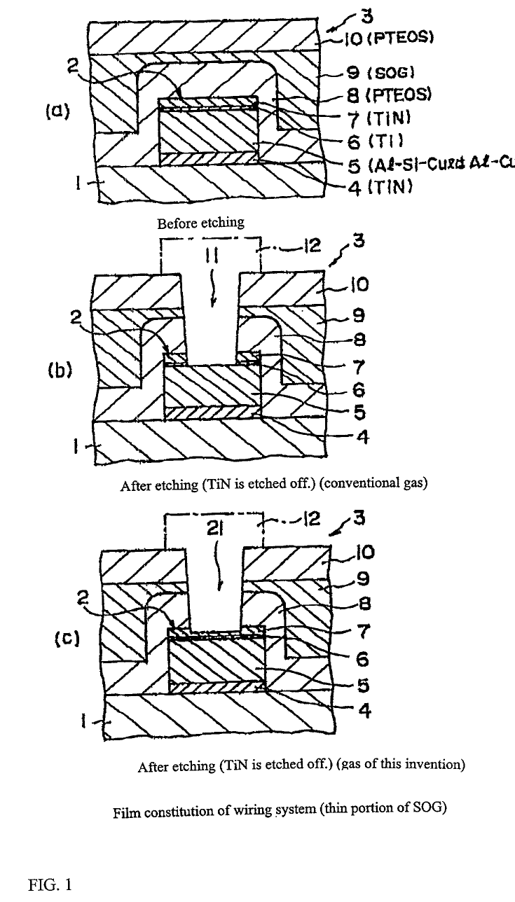

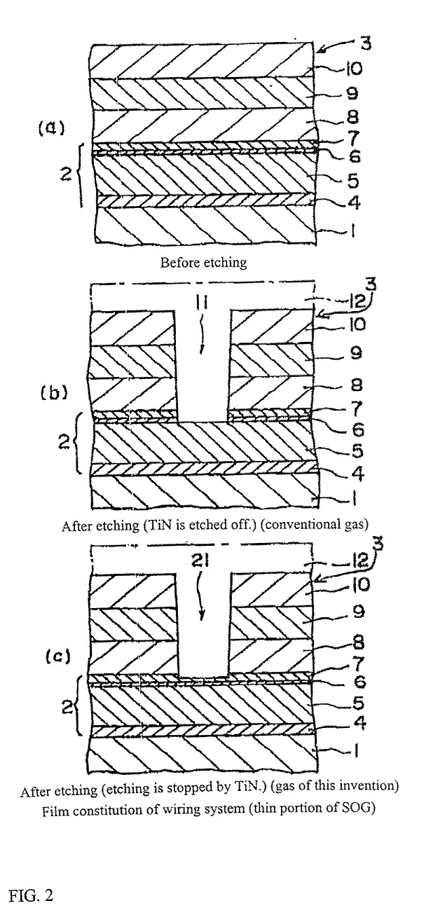

First, as shown in FIG. 1a and FIG. 2a, before a connection hole (via hole) is formed, lower wiring 2, which is made of a stacked structure where TiN layer 4, aluminum alloy layer (for example, Al—Si—Cu or Al—Cu) layer 5, Ti layer 6, and TiN layer 7 are stacked in that order by sputtering or the like, is formed on SiO₂ layer 1 that is provided on a silicon substrate. Then, insulating layer 3 is made of a stacked structure where PTEOS layer 8, SOG layer 9, and PTEOS layer 10, the top layer, are stacked in that order as an interlayer insulating film.

Then, as shown in FIG. 1c and FIG. 2c, using a photoresist with a prescribed pattern (not shown), plasma (dry) etching is performed using a fluorocarbon etching gas based on this invention, and a connection hole (via hole) 21 is formed to reach lower wiring 3 [sic] (in actuality, to the middle position in the thickness of TiN layer 7) through insulating layer 3. In addition, as indicated by the imaginary line, upper wiring 12 is formed by sputtering and lithographic technology and connects with lower wiring 2 through connection hole 21.

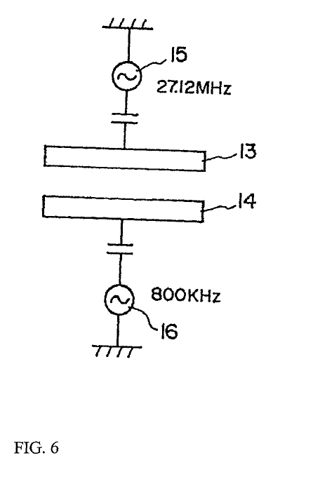

For this plasma etching, in the plasma etching device shown in FIG. 6, a mixed gas, in which CHF₃ gas, an etching gas with a low C/F ratio, is added to C₄F₈, an etching gas with a high C/F ratio, was used as the etching gas, and via hole etching was performed under the conditions below.

C₄F₈/CHF₃/Ar/O₂=15/5/400/10 or 10/10/400/10 sccm, pressure=50 mT,

RF (upper electrode/lower electrode)=2200/1400 W,

back pressure (center section/edge section)=10/35 T,

temperature (lower electrode/upper electrode/titanium bar side wall)=−20/30/40° C.

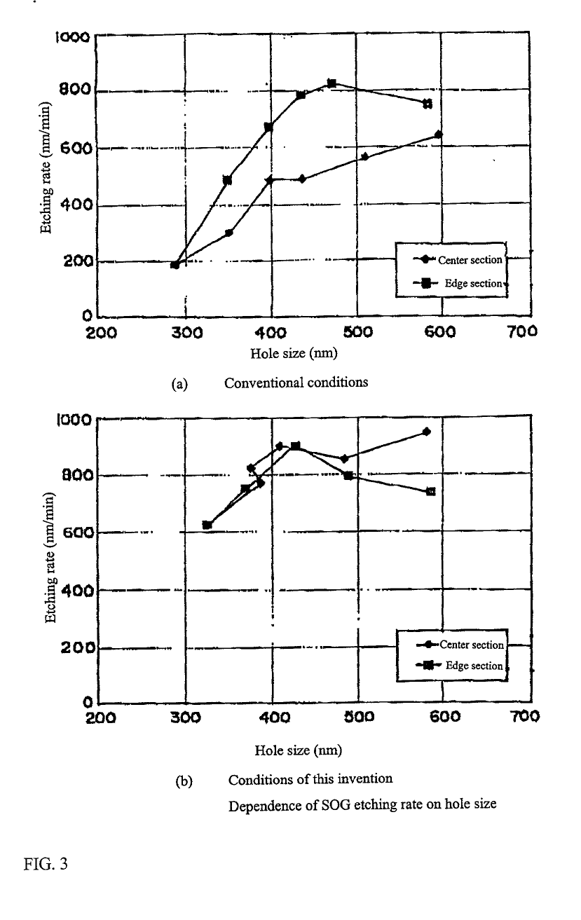

Results when the etching rate of SOG layer 9 was measured for various via hole sizes are shown in FIG. 3b. Here, results obtained with previously discussed conventional conditions (C₄F₈/Ar/O₂=18/420/11) are also shown in FIG. 3a.

According to these results, with the conditions of this invention, for an oxide film, such as an SOG film that has Si—N bonds in the film, a faster etching rate than in the conventional case can be obtained, and it could be seen that etching uniformity is also increased in terms of location. The effect of lowering the etching rate according to the via hole diameter is also smaller than conventionally, and even when the via hole diameter is small (especially 0.3-0.4 μm or even less), there is a high probability that results will be maintained satisfactorily. This is thought to be due to the fact that the F radicals in the plasma are increased by adding CHF₃ gas with a low C/F ratio, to C₄F₈ gas with a high C/F ratio.

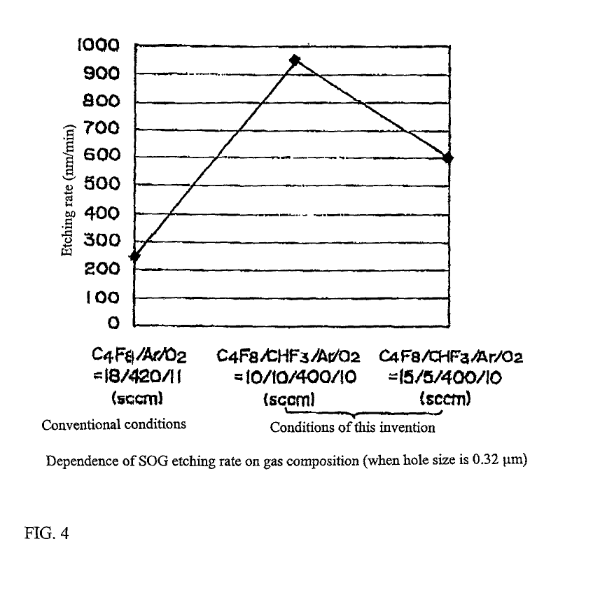

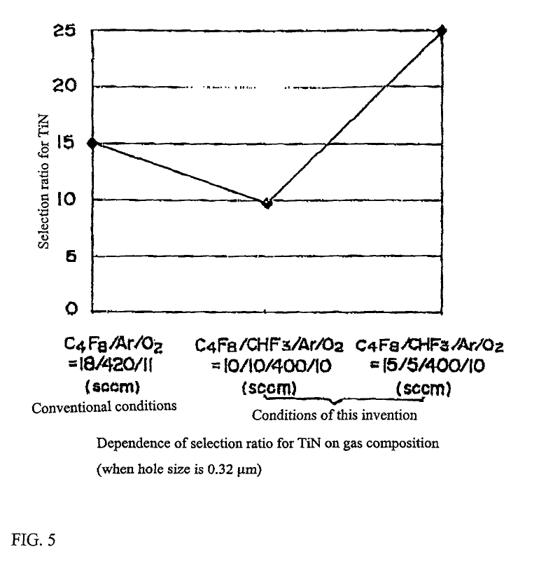

Next, FIG. 4 shows the etching rate of SOG layer 7 and in FIG. 5 shows the selection ratio for TiN layer 7 and the layer on alloy layer 5 in lower wire 2, respectively, compared to a conventional example.

With this, from FIG. 4, it is clear that the SOG etching rate is increased by the conditions of this invention. And from FIG. 5, a selection ratio of 20 or greater was obtained for TiN by the conditions of this invention. This indicates that although there was concern that the selection ratio with TiN would be reduced by an increase in F radicals in the plasma due to the addition of CHF₃ gas, the increase in F radicals was restricted by the H in the CHF₃, and a significant drop in the selection ratio with TiN was avoided. Note that when the ratio at which CHF₃ gas is admixed is increased, although the SOG etching rate increases, conversely, the TiN selection ratio readily drops, so that the mixing ratio should preferably be equal to or less that that of the C₄F₈.

In this way, with the dry etching using the mixed gas of this invention, as shown in FIG. 1c and FIG. 2c, in dry etching of a composite film (insulating layer 3) with an SOG layer that has Si-N bonds in the film and an oxide film, even when SOG layer 8 is thin or thick, it is possible to form via hole 21 reliably with good reproducibility so that etching is stopped at the middle position in the thickness of TiN layer 7, the layer on Al alloy layer 5.

Thus, with a constitution such as this, Al alloy layer 5 is not exposed in via hole 21, so there is no fluorinating of the surface of the Al alloy layer, contact resistance between the upper and lower wirings will be small, and its uniformity will also be good.

The preferred embodiment of this invention discussed above can be further varied based on the technical idea of this invention.

With the aforementioned example, a small quantity of CHF₃, with a low C/F ratio, was added to C₄F₈/Ar/O₂, a mixed gas with C₄F₈, with a high C/F ratio, but even when CF₄, with a lower C/F ratio than CHF₃ gas, is used, the SOG etching rate can be increased. Here, there are more F radicals compared to CHF₃, so it is thought that the selection ratio for TiN will be lower than with CHF₃. Thus, with a gas with a low C/F ratio, the same results are obtained even with a gas containing H, for example, CH₂F₂, that will prevent an extreme increase in F radicals. Especially when etching with a device that can generate high-density plasma, when a gas containing H is used to prevent the selection ratio with TiN from dropping due to an increase in F radicals when CFx radicals reseparate, this is effective as a method for suppressing significant production of F radicals.

In addition to this, the materials of each part of the aforementioned multilayer wiring structure can be varied in many ways, and the device constitutions to which this invention can be applied are not limited to the aforementioned. Also, this invention is not limited to the aforementioned multilayer wiring, but can also be applied to formation of contact holes for connecting with semiconductor substrates, or the like.

With the manufacturing method of this invention, an insulating film, such as SOG, is etched using a gas mixture of a gas with a low C/F ratio, such as CHF₃, and a gas with a high C/F ratio, such as C₄F₈/Ar/O₂, so the F radicals in the plasma are increased by the addition of the gas with a low C/F ratio. Because of this, the etching rate of SOG, which contains Si—N bonds, is also increased, and even if the F radicals increase, an extreme increase in F radicals is restricted by the reaction of F radicals caused by H in the gas, and a TiN selection ratio of 20 or greater can be increased.

Thus, the semiconductor device produced with the manufacturing method of this invention will have a unique structure where a connection hole is formed to the middle position of the thickness of the TiN layer, and it will be superior in terms of contact resistance reduction and uniformity.

1. Semiconductor device manufacturing method that includes a process where an insulating layer on a semiconductor substrate is etched using a mixed gas of multiple types of fluorocarbon gases that have different ratios of carbon atoms to fluorine atoms (hereafter called C/F ratio).

2. Semiconductor device manufacturing method described in claim 1 that uses the aforementioned mixed gas where equal amounts or less of a second fluorocarbon gas with a small C/F ratio to a first fluorocarbon gas with a large C/F ratio are mixed.

3. Semiconductor device manufacturing method described in claim 2 where C₄F₈ is used as the aforementioned first fluorocarbon gas and at least one selected from the group composed of CHF₃, CH₂F₂ and CF₄ is used as the aforementioned second fluorocarbon gas.

4. Semiconductor device manufacturing method described in claim 1 where the aforementioned insulating layer is plasma-etched with the aforementioned mixed gas of fluorocarbon gases.

5. Semiconductor manufacturing device described in claim 1 where a lower conducting layer is formed on the aforementioned semiconductor substrate as an electrode or wiring, a connection hole is formed by the aforementioned etching in the aforementioned insulating layer that covers this lower conducting layer, and an upper conducting layer that is connected to the aforementioned lower conducting layer is formed in the aforementioned connection hole as an electrode or wiring.

6. Semiconductor device manufacturing method described in claim 5 where the aforementioned lower conducting layer has a titanium nitride layer on the surface where the aforementioned connection hole is formed and the aforementioned insulating layer includes a spin-on glass layer.

7. Semiconductor device manufacturing method described in claim 6 where the aforementioned lower conducting layer is made of a stacked structure where a titanium nitride layer, a layer of aluminum or an alloy thereof, a titanium layer, and a titanium nitride layer are stacked in that order, and the aforementioned insulating layer is made of a stacked structure where a silicon oxide layer formed from tetraethyl/orthosilicate, a spin-on glass layer, and a silicon oxide layer formed from tetraethyl/orthosilicate are stacked in that order.

8. Semiconductor device in which a lower conducting layer that has a titanium nitride layer on its surface is formed on the semiconductor substrate as an electrode or wiring, a connection hole is formed in an insulating layer that includes a spin-on glass layer to cover this lower conducting layer, and an upper conducting layer that is connected to the aforementioned lower electrode layer is formed in the aforementioned connection hole as an electrode or wiring, where the aforementioned connection hole is formed to the center position of the thickness of the aforementioned titanium nitride layer through the aforementioned insulating layer.

9. Semiconductor device described in claim 8 where the aforementioned lower conducting layer is made of a stacked structure where a titanium nitride layer, a layer of aluminum or an alloy thereof, a titanium layer, and a titanium nitride layer are stacked in that order, and the aforementioned insulating layer is made of a stacked structure where a silicon oxide layer formed from tetraethyl orthosilicate, a spin-on glass layer, and a silicon oxide layer formed from tetraethyl orthosilicate are stacked in that order.
